(19) United States
(12) Patent Application Publication
(10) Pub. No.: US 2006/0246724 A1
(43) Pub. Date: Nov. 2, 2006

(54) Method for polishing wafer

(76) Inventor: Naoyuki Takamatsu, Fukushima (JP)

Correspondence Address: MCGLEW & TUTTLE, PC, P.O. BOX 9227, SCARBOROUGH STATION, SCARBOROUGH, NY, 10510-9227, US

(21) Appl. No.: 10/565,879

(22) PCT Filed: Jul. 8, 2004
(86) PCT No.: PCT/JP04/09731

§ 371 Date: Jan. 23, 2006

(30) Foreign Application Priority Data
Jul. 24, 2003 (JP) 2003-278970

(51) Int. Cl. H01L 21/461; C03C 15/00; B44C 1/22

(52) U.S. Cl. 438/692; 216/88

(57) ABSTRACT

There is provided a method for polishing a wafer in which linear defects are not generated. The polishing method comprises the steps of: holding a wafer on a rotatable wafer holding plate; and polishing a surface of the being in contact with a polishing cloth adhered on a rotatable table in such a state that a polishing agent is supplied onto the polishing cloth, wherein the polishing agent is an alkaline solution which contains silica having particles each in the shape of almost an sphere as a main component and further an organic base or a salt thereof. A quaternary ammonium hydroxide is used as the organic base or the salt thereof.

### TECHNICAL FIELD

The present invention relates to improvements on a method for polishing a wafer such as a silicon wafer.

### BACKGROUND ART

Conventionally, a method for manufacturing a silicon wafer serving as a semiconductor substrate material being used in a memory device or the like generally includes: a single crystal growing process for producing a single crystal ingot with a Czochralski (CZ) method, a Floating Zone (FZ) method and other methods; and a wafer manufacturing (processing) process in which the single crystal ingot is sliced into wafers and at least one main surface of the sliced wafer is processed into a mirror-polished wafer. Devices are fabricated on thus manufactured mirror-polished wafer.

To show the wafer manufacturing (processing) process in a more detailed manner, the process includes: a slicing step for slicing an single crystal ingot to obtain thin disc-like wafers; a chamfering step for chamfering the outer peripheral portion in order to prevent the wafer obtained in the slicing step from breakage or chipping; a lapping step for flattening the chamfered wafer; an etching step for removing work damage remaining in the chamfered and lapped wafer; a polishing step for mirror-polishing surfaces of the etched wafer; and a cleaning step for washing the polished wafer to remove a polishing agent or foreign matters attached on the polished wafer. The wafer manufacturing process shows main steps thereof to which other steps such as a surface grinding step and a heat treating step may be added, or in which one step may be divided into multiple stages or the order of the steps may be interchanged.

Especially, the polishing step is divided into a primary polishing step called rough polishing and a final polishing step called precision polishing. The primary polishing step is further divided into two or more steps when required, in which case the steps are called a primary polishing step, a secondary polishing step and so on.

In the polishing step, a wafer such as an etched silicon wafer held on a wafer holding plate of a polishing head is brought into contact with a rotating polishing cloth on a table under a proper pressure so that the wafer is polished. In the polishing, there is employed an alkaline solution containing colloidal silica (called a slurry or a polishing agent). Such a polishing agent is supplied into between contact surfaces of the polishing cloth and the silicon wafer to thereby cause a mechanochemical action therebetween and to advance the polishing.

Polishing apparatuses of various types have been employed. For example, there is known a polishing apparatus of a batch type in which, as shown in FIG. 3, plural wafers are polished in the state where the plural wafers are held on one polishing head. In FIG. 3, the polishing apparatus A has a polishing table 30 rotated by a rotary shaft 37 at a predetermined number of rotation. A polishing cloth P is adhered on the top surface of the polishing table 30.

Numerical symbol 33 indicates a work holding plate, which is rotated by a rotary shaft 38 via an upper load 35 and is vibrated by a vibrating means. Plural wafers W are held on the lower surface of the work holding plate 33 by means of adhesion, and in this state, pressed down onto a surface of the polishing cloth P, while a slurry (polishing agent) 39 is simultaneously supplied onto the polishing cloth P at a predetermined flow rate through a slurry supply pipe 34 from a slurry supply apparatus (not shown) and a to-be-polished surface of each wafer W is rubbed against the surface of the polishing cloth P with the slurry 39 to thereby polish the wafer W.

In addition thereto, there is a single wafer type polishing apparatus in which one wafer is held on one polishing head and in this state, polished. Still in addition thereto, there are many types of holding wafers, for example, by vacuum chucking them, by adhering them onto a work holding plate with wax, adhering them using a surface tension of water and other holding means. The polishing apparatuses described above are of a type in which one surface of each wafer is polished, and further in addition thereto, there has been a polishing apparatus in which both surfaces of each wafer are simultaneously polished.

### DISCLOSURE OF THE INVENTION

### Problems to Be Solved by the Invention

There has been a case where if an epitaxial growth is performed on a surface of a wafer obtained by polishing the wafer so as to be flat and in a mirror surface in the above-mentioned polishing step, a defect is observed on the surface of the epitaxial wafer. Serious investigations have been conducted on the defect, with the result that a linear defect is observed on the mirror polished wafer serving as the epitaxial substrate (hereinafter referred to as a linear defect). It has been clear that the defect is generated in the polishing step.

The linear detect is a micro-defect that could almost not be detected with a conventional inspecting instrument, whereas the defect is easily observed on a surface of a silicon wafer, for example, using a laser microscope with a confocal optical system. The feature of the defect resides in a shape of a linear protrusion with a height of several nm and a length of about 0.5 μm or more.

Therefore, it is an object of the present invention to provide a method for polishing a wafer in which such linear defects are not generated.

### Means to Solve Problems

The inventor has conducted serious studies, with the result that it is clear that one of causes for generation of this linear defect is a polishing agent.

Generation of such a defect may be caused in a case where, especially, Na₂CO₃ for pH adjustment that has been conventionally used is excessively added. This is considered because silica being used as a main component of a polishing agent causes micro-aggregation by excessive addition of Na₂CO₃ to thereby exert an adverse effect on a wafer surface.

That is, it has also been cleared that shapes, particle diameters, and a degree of dispersion of silica contained in the polishing agent affects greatly to the surface of the polished wafer. A first aspect of a method for polishing a wafer comprises the steps of holding a wafer on a rotatable wafer holding plate, and polishing a surface of the wafer being in contact with a polishing cloth adhered on a rotatable table in such a state that a polishing agent is supplied onto the polishing cloth, wherein the polishing agent is an alkaline solution which contains silica having particles each in the shape of almost an sphere as a main component and further an organic base or a salt thereof.

A second aspect of a method for polishing a wafer of the present invention comprises the steps of holding a wafer on a rotatable wafer holding plate, and polishing a surface of the wafer being in contact with a polishing cloth adhered on a rotatable table in such a state that a polishing agent is supplied onto the polishing cloth, wherein the polishing agent is an alkaline solution which contains silica dispersed almost uniformly, the silica having particles each in the shape of almost an sphere and an average particle diameter of 12 nm or less.

Especially, an average particle diameter of the silica in a dispersion state is preferably in the range of from 5 nm to 10 nm and a maximum particle diameter of the silica in a dispersion state is preferably 12 nm or less. In such conditions, linear defects can be greatly reduced.

The wafer is preferably polished in a state that a pH value of the alkaline solution is in the range of from 10 to 13. Na₂CO₃ is preferably used for pH adjustment of the alkaline solution during polishing. These conditions lead to an increase as well as a stability of a polishing rate. Though Na₂CO₃ is one of causes for aggregation of the silica, it is easy in pH adjustment and handling in operation.

The polishing agent to be used in the second aspect of the method for polishing a wafer of the present invention, as in a case of the first aspect of the method for polishing a wafer of the present invention, may contain the silica as a main component and may be an alkaline solution containing an organic base or a salt thereof.

The organic base or the salt thereof may be added instead of sodium carbonate (Na₂CO₃) and may be added together with sodium carbonate (Na₂CO₃). Quaternary ammonium hydroxides or the like may be especially used as the organic base or the salt thereof and, for example, the following chemical species can be named.

Quaternary ammonium hydroxides include: tetramethyl ammonium hydroxide (TMAH), tetraethyl ammonium hydroxide (TEAH), methyltriethyl ammonium hydroxide, tetrapropyl ammonium hydroxide, tetrabutyl ammonium hydroxide, methyltributyl ammonium hydroxide, cetyltrimethyl ammonium hydroxide, choline, trimethylbenzyl ammonium hydroxide and the like.

Addition of one of the organic bases and the salts thereof can improve dispersibility, prevent aggregation of the silica and suppress generation of the linear defects. There are some cases where the organic bases and the salts thereof improve the dispersibility, and in the cases it is preferable to use plural amines and quaternary ammonium hydroxides in combination.

It is better to use a polishing agent to which an organic base or a salt thereof, for example, a quaternary ammonium hydroxide, especially, TMAH, is added. The organic base or the salt thereof is preferably added up to a dissolution limit of the polishing agent in use. The above-mentioned polishing agent leads to an increase of the polishing rate as well as easiness in removal thereof by cleaning after polishing. Even in a case where Na₂CO₃ is excessively added, no aggregation occurs. Incidentally, a quaternary ammonium hydroxide, for example, TMAH itself is not a dispersant, but it is conceived that since a molecule thererof has a steric structure, aggregation of the silica is hindered.

The wafer may be a silicon wafer. It is preferable to perform the polishing method of the present invention in a rough polishing step (a primary polishing step and a secondary polishing step) in a mirror polishing process. It is preferable to use the polishing agent with a silica concentration in the range of from 2 to 20 wt % in the above step.

In the above step, stock removal of the wafer is comparatively as large as 1 μm or more and polishing conditions such as a polishing pressure are severely set and a polishing rate is comparatively high. Therefore, in the step, a mechanical action is comparatively large and hence by contact between the polishing agent and the wafer a linear defect is easily generated. Accordingly, by applying the method for polishing a wafer of the present invention to the above step, generation of a linear defect can be prevented from occurring.

### Effect of the Invention

According to the method for polishing a wafer of the present invention, a linear defect that has been conventionally generated after polishing of a wafer is prevented from occurring, and a mirror polished wafer with an excellent surface state can be manufactured.

### BRIEF DESCRIPTION OF THE DRAWINGS

FIG. 1 is a schematic explanatory side view showing a polishing apparatus and a slurry supply circulation system to be used in the method of the present invention.

FIG. 2 is a photograph showing one example of a linear defect observed on a wafer surface by a laser microscope having a confocal optical system.

FIG. 3 is a schematic explanatory side view showing one example of a polishing apparatus.

### DESCRIPTION OF SYMBOLS

30: a polishing table, 33: a work holding plate, 34: a slurry supply pipe, 35: an upper load, 37: a rotary shaft, 38: a rotary shaft, 39: slurry, 39a: new slurry liquid, 39b: used slurry, 50: a slurry supply tank, 52: a slurry preparation tank, 54: an undiluted slurry liquid supply pipe, 56: a pure water supply pipe, 58: an additive supply pipe, 60, 74: pH meters, 62: a new slurry liquid supply pipe, 64: slurry collecting tank, 66: drainage port, 68: slurry collecting pipe, 70: a pump, 72: a pH adjusting agent supply pipe, A: a polishing apparatus, B: a slurry supply circulation system, P: a polishing cloth, W: a wafer

### BEST MODE FOR CARRYING OUT THE INVENTION

Description will be given of an embodiment of a polishing apparatus and a slurry supply circulation system to be used in a method for polishing a wafer of the present invention below with reference to the accompanying drawings.

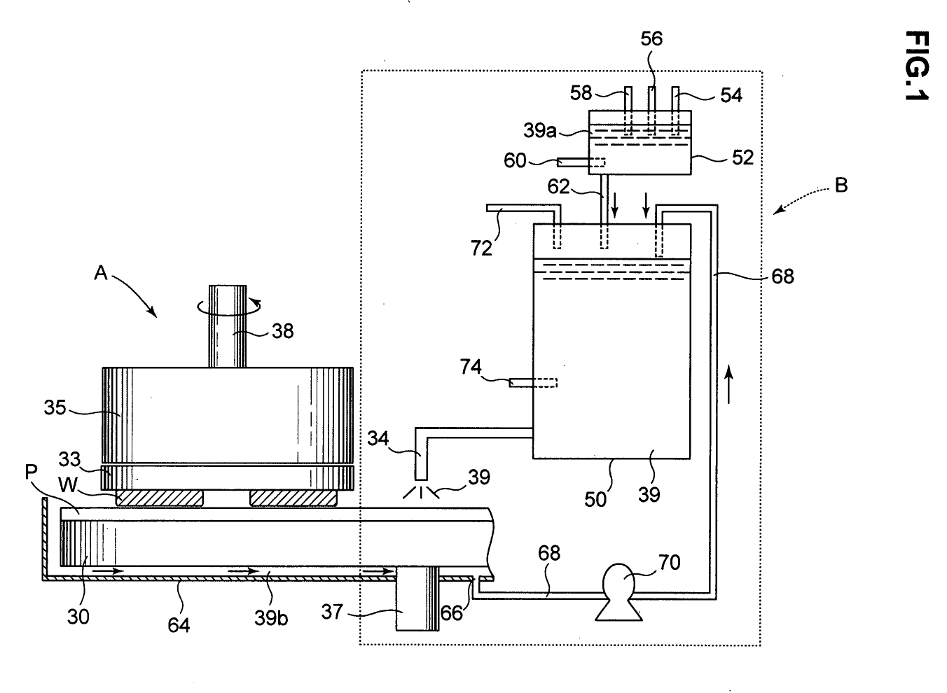

FIG. 1 is a schematic explanatory side view showing a polishing apparatus and a slurry supply circulation system to be used in the polishing method of the present invention.

In FIG. 1, the polishing apparatus A has the same construction as the polishing apparatus shown in FIG. 3. Description will be given of an embodiment in which a slurry supply circulation system B is installed with the polishing apparatus A. That is, the polishing apparatus A has a polishing table 30 rotated by a rotary shaft 37. A polishing cloth P is stuck on the top surface of the polishing table 30.

Numerical symbol 33 indicates a work holding plate, which is rotated by a rotary shaft 38 via an upper load 35 and vibrated by vibrating means. Plural wafers W are held on the lower surface of the work holding plate 33 and in this state, pressed down to the surface of the polishing cloth P, while a slurry (a polishing agent) 39 is simultaneously supplied onto the polishing cloth P through a slurry supply pipe 34 from a slurry supply tank 50 of the slurry supply circulation system B, and a surface to be polished of the wafer W is in contact with the surface of the polishing cloth P via the slurry 39 to polish the wafer.

A slurry preparation tank 52 is installed above the slurry supply tank 50. The slurry preparation tank 52 is provided with a starting slurry supply pipe 54 through which a starting slurry is supplied, a pure water supply pipe 56 through which pure water is supplied, and an additive supply pipe 58 through which additives such as a pH adjusting agent and an organic base are supplied, so that a new slurry liquid 39a with a desired composition can be prepared. Numerical symbol 60 indicates a pH meter measuring a pH value of the new slurry liquid 39a prepared in the slurry preparation tank 52, and using the pH meter, pH control of the new slurry liquid 39a is conducted.

The new slurry liquid 39a prepared in the slurry preparation tank 52 is supplied into the slurry supply tank 50 through a new slurry liquid supply pipe 62. On the other hand, the slurry 39 supplied onto the polishing cloth P through the slurry supply pipe 34 flows down while exerting a polishing action and is collected into a slurry collecting tank 64 provided below the table 30. The collected used slurry 39b is sent under pressure by a pump 70 into the slurry supply tank 50 through a slurry collecting pipe 68 connecting to a drainage port 66 open at the bottom portion of the slurry collecting tank 64, thereby the slurry 39b being collected. Numerical symbol 72 indicates a pH adjusting agent supply pipe for supplying a pH adjusting agent into the slurry supply tank 50.

Hence, the used slurry 39b, the new slurry liquid 39a and the pH adjusting agent are supplied into the slurry supply tank 50 to prepare the polishing slurry 39 with a desired composition. Numerical symbol 74 indicates a pH meter measuring a pH value of the slurry 39 prepared in the slurry supply tank 50, with which pH control of the slurry 39 is conducted.

By connecting the slurry supply circulation system B with the above construction to the polishing apparatus A, the used slurry 39b is recovered and reused by circulation, which realizes effective use of the slurry. Incidentally, in a case where the slurry is circulated and used in this way, depending on a quantity of polishing dust (for example, polishing cloth dust), a filter or the like that removes the polishing dust is installed properly in the slurry collecting pipe 68 or the slurry supply pipe 34.

Further, detailed description will be given of a method for polishing a wafer of the present invention. The polishing agent to be used in the method for polishing a wafer of the present invention is an alkaline solution constituted of solid components, various kinds of additives and pure water.

The solid components in the polishing agent are silica particles each having a almost spherical shape. The silica is used in a state where the dispersibility thereof is improved by adding an organic base and a salt thereof. The polishing agent contains silica dispersed almost uniformly therein and an average particle diameter of the silica in dispersion is 12 nm or less and preferably in the range of from 5 to 10 nm. If the average particle diameter of the silica is less than 5 nm, it is difficult to make the silica each having a spherical shape with the result that the shape stability of the silica becomes worse unpreferably, while if the average particle diameter thereof exceeds 12 mm, the generation of linear defects increases unpreferably.

Incidentally, there is only required in the above range the average particle diameter of the silica in a dispersion state in the polishing agent to be used in the method for polishing a wafer of the present invention, while an individual particle diameter each of the silica is preferably so as not to exceed the above range. That is, the maximum particle diameter is preferably 12 nm or less. Incidentally, the values of the average diameter and the maximum particle diameter are confirmed by means of a BET method.

Besides, as the silica to be employed in the method of the present invention, any of silica can be used if an average particle diameter and a shape of the silica particle in a dispersion state in the wafer polishing agent to be used in the method of the present invention belong to the above definition. For example, there may be used powdered silica and preferably aqueous colloidal silica (silica sol) liquid produced from water glass in terms of dispersion stability. Also, the aqueous colloidal silica liquid is preferably alkaline because a pH condition of a polishing agent for a wafer is easily adjustable. However, it is necessary that the shape of the above silica is almost spherical. As the silica gets out of shape more, generation of the linear defects increases. To this end, there can be used the alkaline colloidal silica product generally put on the market.

The polishing agent to be used in the method for polishing a wafer of the present invention is preferably controlled in the pH value range of from 10 to 13. Especially when using the polishing agent or polishing the wafer with the polishing agent, it is preferably used in the pH value range of from 10.5 to 11.5. If the pH value is less than the above range, a polishing effect is worse and practicability is poor, while if the pH value exceeds the above range, the polishing agent (silica) may aggregate, which is not preferable. Incidentally, the pH value is adjustable by employing known alkaline agents (for example, NaOH, KOH, ammonia, organic amines or the like) as additives before use of the polishing agent. The used polishing agent for polishing is repeatedly reused (circulation use). In this case, the pH value of the used polishing agent is finely adjusted with Na₂CO₃ or the like that can easily control the pH value.

Further, a polishing agent to be used in a polishing method of the present invention requires silica being sufficiently dispersed therein. The silica is preferably treated or includes additives such that the silica particles do not aggregate each other. No specific limitation is placed on the method for dispersing the silica particles and for the purpose an organic base or a salt thereof is added, for example.

A quaternary ammonium hydroxide or the like can be used as the organic base or the salt thereof. It is especially preferable to employ the organic base or the salt thereof a molecule of which has a steric structure to thereby prevent the silica from aggregation.

Especially, in order to disperse the silica sufficiently, it is preferable to add tetramethyl ammonium hydroxide (TMAH). When TMAH is thus added in the polishing agent, TMAH acts so as to cover the silica particle surface (to be adsorbed thereon), which reduces the chance where the silica particles aggregate each other with the result that the uniform dispersion thereof is achieved. It is also preferable to use another polishing agent in which silica particles do not aggregate each other to obtain a good dispersion state by coating the silica particle surface in an active state with alumina in a similar way.

The more the silica particles disperse, the better the polishing agent is, and hence it is preferable to add additives such as organic bases as much as possible. However, some of the organic bases contain heavy metals and therefore it is preferable to add the organic bases at a level that they do not contaminate a wafer.

Especially, TMAH has no influence of heavy metals and it is preferable to add TMAH as much as possible. TMAH may be added up to a dissolution limit in the polishing agent but in content of at least 5 wt % of a total amount of the polishing agent. Incidentally, the upper dissolution limit of TMAH depends upon a solvent to be used (usually a solution obtained by adding alkaline components to pure water), a temperature of use or the like.

No specific limitation is placed on a solid component (silica) concentration in a polishing agent (especially an undiluted liquid) for polishing a wafer. In preparation of the polishing agent, the solid component (silica) concentration may be generally in the range of 5 to 80 wt %, preferably 10 to 70 wt %. When using the polishing agent, it is diluted with water so that the solid component concentration (silica concentration) is in the range of 2 to 20 wt % relative to the entire composition. A concentration or the like of the polishing agent when polishing may be set properly depending upon a construction of a polishing apparatus, polishing conditions and the like.

The polishing agent with the composition described above is used to polish a wafer. Incidentally, while in order to generate no linear defect, there are especially important the shapes and diameters of the silica particles and the dispersion state thereof, problems associated with increase in a polishing rate and metal contamination are also to be solved for using them as the polishing agent. Though the problems are solved to some extent by using an additive such as TMAH, it is preferable to add materials having a chelating effect such as sodium tripolyphosphate or other chelating agents. In order to increase the polishing rate, organic amines, piperazine or others are arbitrarily added. It is preferable to use ion exchange resins and the like in the production stage of the silica particles to thereby remove heavy metals and others sufficiently. It is preferable that Cu and Ni concentrations in the polishing agent are controlled to 1 ppb or less.

Also, for this polishing, a polishing cloth of an unwoven cloth type is very effective, and especially a polishing cloth with hardness (Asker C hardness) of 50 or more is used in a polishing step with a great effect. It is thought that a cause for generation of linear defects is mainly an influence of a polishing agent, and when using a polishing cloth of this type, liner defects are greatly generated in the primary polishing and the secondary polishing; therefore compatibility between the polishing agent and the polishing cloth may be one of causes for generation of the linear defects. With the polishing method of the present invention, even if the above polishing cloth is used, generation of the linear defects can be prevented. Incidentally, the term “Asker C hardness” is a value measured with a C type Asker rubber hardness meter that is one kind of a spring hardness tester and obtained according to SRIS (The Society of Rubber Industry, Japan standards) 0101.

### EXAMPLES

Description will be given of the present invention in a more detailed manner below with examples, but it is needless to say that the examples are presented by way of illustration and not to be taken by way of limitation.

### Examples 1 to 3 and Comparative Examples 1 to 3

There are shown results of confirmation of an influence of a polishing agent (especially, a particle diameter, a particle shape and dispersibility) on a linear defect. As a solid component contained in the polishing agent, there is used silica sol obtained in such a way that Na water glass is ion exchanged to obtain an active silicic acid and the active silicic acid is heated to be polycondensated. Pure water and NaOH for pH adjustment are added into the silica sol to prepare a polishing agent with a solid component (silica) concentration of 50%. Tripolyphosphoric acid is further added to the polishing agent.

Using the above polishing agent as a base component, six kinds of polishing agents were prepared so as to have different average particle diameters and shapes of silica as shown in the following (1) to (6). Average particle diameters and shapes of the silica can be controlled by changing the polycondensation process for making the silica sol and other processes. Then, there were prepared several polishing agents having different levels which contain silica different in particle diameter and particle shape and relationships between the respective polishing agents and linear defects appearing after polishing were confirmed.

(1) A polishing agent (therein, silica particles easily aggregate together during polishing and silica was not dispersed uniformly) was prepared by adding Na₂CO₃ to thereby adjust a pH value. The polishing agent had an average silica particle diameter of about 13 nm and silica particles of spherical shapes (Comparative Example 1).

(2) A polishing agent (therein, silica particles are of not spherical shapes) was prepared by adding Na₂CO₃ to thereby adjust a pH value. The polishing agent had an average silica particle diameter of about 13 nm and silica particles of distorted shapes (Comparative Example 2).

(3) A polishing agent (therein, an average silica particle is large) was prepared by adding Na₂CO₃ to thereby adjust a pH value. The polishing agent had an average silica particle diameter of about 20 nm (the maximum particle diameter of the order of about 60 nm) and silica particles of spherical shapes of a sphere (Comparative Example 3).

(4) A polishing agent (therein, the silica particles are good in dispersion even during polishing, the particle diameters are small and the particle shapes are spherical) was prepared by adding TMAH of about 10 wt %. The polishing agent had an average silica particle diameter of about 12 nm (the maximum particle diameter of about 15 nm and the minimum particle diameter of about 8 nm) and silica particles of spherical shapes (Example 1).

(5) A polishing agent (therein, silica particles are good in dispersion even during polishing, particle diameters are smaller and particle shapes are spherical) was prepared by adding TMAH of about 10 wt %. The polishing agent had an average silica particle diameter of about 8 nm (the maximum particle diameter of about 12 nm and the minimum particle diameter of about 5 nm) and silica particles of spherical shapes (Example 2).

(6) A polishing agent (therein, silica particles are good in dispersion even during polishing, particle diameters are small and particle shapes are spherical) was prepared by adding TMAH up to the dissolution limit (20 wt % in a case of the present polishing agent). The polishing agent had an average silica particle diameter of about 8 nm (the maximum particle diameter of about 12 nm and the minimum particle diameter of about 5 nm) and silica particles of spherical shapes (Example 3).

No specific limitation is placed on a polishing apparatus for a wafer and polishing conditions. In these examples, there was employed a single side polishing apparatus using a polishing head that can simultaneously hold two wafers each of 300 mm in diameter.

The polishing procedure was as follows: two both-side polished silicon wafers (the first polishing has been finished) were adhered onto the wafer holding plate of the polishing head as one batch and polished using a polishing cloth constituted of an unwoven cloth. The above polishing agent was added at a rate of 8 l/min in polishing. The polishing agent was diluted by pure water so that the silica concentration is 3.0 wt %, and then the diluted polishing agent was used. Further, Na₂CO₃ was added for adjustment of the pH value. The initial pH value was adjusted to 10.5.

The polishing conditions were as follows: a polishing cloth of an unwoven cloth type (Asker C hardness of 80) was used, a polishing pressure was set to 20 kPa and a surface of the silicon wafer was polished so that the stock removal was about 1.5 nm. These polishing conditions correspond to those of the secondary polishing.

The surface of thus polished wafer was observed on defects using a laser microscope having a confocal optical system (manufactured by Laser Tech Co. with a trade name of MAGICS).

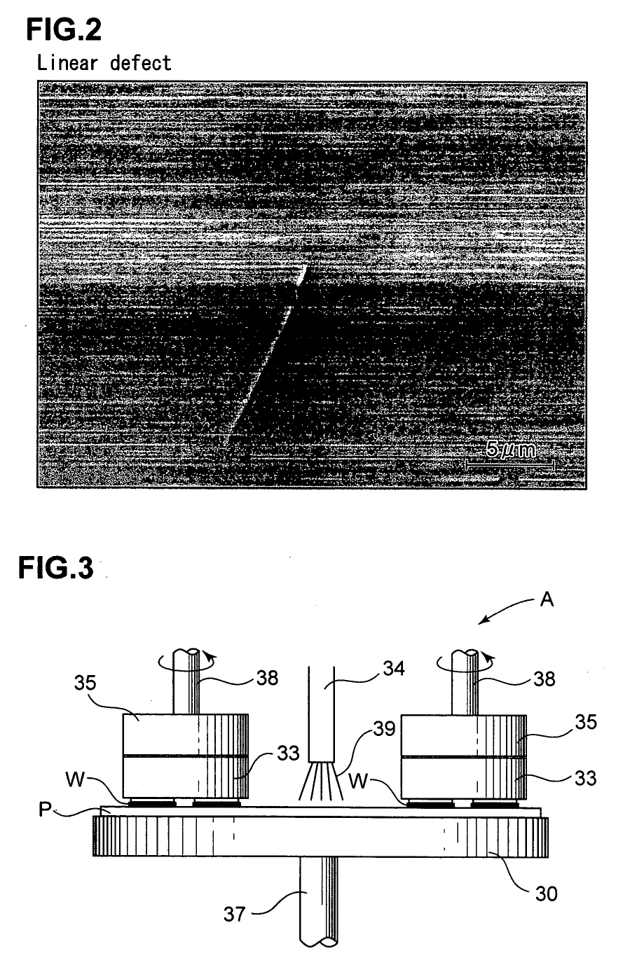

As a result, there were observed linear defects as shown in FIG. 2 in cases where the polishing agents of Comparative Examples 1 to 3 were adopted.

In a case where the polishing agent of Comparative Example 1 was used, the number of such defects was very large, amounting to 100 counts (a 300 mm wafer). Since the same polishing agent was repeatedly used, Na₂CO₃ was added for adjustment of the pH value in the course of the polishing. Though the linear defects were not many at the first stage, the polishing agent caused micro aggregation when Na₂CO₃ was added to some extent, dispersion was deteriorated and in company therewith, generation of the linear defects increased rapidly. It was found from this result that the dispersion state of silica during polishing is important.

In the polishing agent of Comparative Example 2, there were used silica particles each in the distorted shape obtained by acid-treating silica particles each in the spherical shape. It was found that generation of linear defects is accelerated when the spherical shape is slightly distorted. Especially, in this polishing, very many defects, amounting to 1000 counts (a 300 mm wafer) were present. It was found from this fact that the shape each of the silica particles is preferably as close to a sphere as possible.

In the polishing agent of Comparative Example 3, there were used silica particles each with a comparative large diameter. In this polishing, linear defects of the order of 150 counts (a 300 mm wafer) were observed. It was found that though particle diameter each of the silica particles does not affect so much, if the particle diameter is enlarged, the linear defects tend to increase slightly.

On the other hand, in Examples 1 to 3, the linear defects were greatly reduced.

In the polishing agent of Example 1, there was added TMAH as an organic base at a content of the order of 10 wt % to thereby attain better dispersion of the silica particles and besides there were used spherical silica particles each with as a small diameter as possible. By using the above polishing agent, generation of the linear defects was greatly reduced. Especially, in this polishing, the number of the linear defects was very small, amounting to only 30 counts (a 300 mm wafer).

The polishing agent of Example 2 contains silica particles each having a smaller diameter. With such silica particles each having a smaller diameter, silica was prevented from aggregation to thereby perform stable polishing if the polishing agent was repeatedly used (even if Na₂CO₃ or the like was added). Especially, in this polishing, generation of linear defects was greatly reduced, amounting to only 20 counts (a 300 mm wafer).

The polishing agent of Example 3 contains TMAH dissolved up to the dissolution limit. With such polishing agent, generation of linear defects was suppressed and silica was prevented from aggregation to thereby increase the polishing rate and perform stable polishing if the polishing agent was repeatedly used (even if Na₂CO₃ or the like was added). Especially, in this polishing, almost no generation of linear defects was observed.

### Example 4

Description will be given of a case where a silicon wafer is polished by means of a method for polishing a wafer of the present invention below. Three-stage single side polishing including primary, secondary and final polishing was conducted on an etched silicon wafer of 200 mm in diameter. A polishing method of the present invention was applied to the primary and secondary polishing.

That is, in the first and second polishing, there was employed a polishing agent obtained by diluting an alkaline colloidal silica undiluted liquid (a polishing agent) with pure water so that a concentration of a silica solid component was 3 wt % and the pH value was in the range of from 10 to 11. The property of the above alkaline colloidal silica undiluted liquid was as follows: TMAH was added at 20 wt %, an average particle diameter of the silica was about 8 mm (the maximum particle diameter of about 12 nm and the minimum particle diameter of about 5 nm), and the silica solid component was of 30 wt %

(Primary Polishing)

In the primary polishing, there was employed a batch type, wax-mount, single side polishing apparatus as shown in FIG. 1 as a polishing apparatus. Polishing conditions were such that a polishing cloth of an unwoven cloth type (Asker C hardness of 60) was used to polish a silicon wafer surface with stock removal of about 10 μm under a polishing pressure of 30 kPa. These polishing conditions correspond to those for polishing called the primary polishing. Five silicon wafers each of 200 mm in diameter were polished in one batch and a total of twenty batches were polished.

The polishing agent was used by circulation and repeatedly used for polishing plural wafers. At this time, the pH value adjustment was conducted with Na₂CO₃. The initial pH value was adjusted to 10.5. The flow rate of the polishing agent was 10 l/min.

(Secondary Polishing)

In the second polishing as well, there was employed a single side polishing apparatus as shown in FIG. 1 as a polishing apparatus. Polishing conditions were such that a polishing cloth of an unwoven cloth type (Asker C hardness of 80) was used to polish a silicon wafer surface with stock removal of about 1.5 μm under a polishing pressure of 20 kPa. The polishing conditions correspond to those for polishing called the secondary polishing.

The polishing agent was also used by circulation in the second polishing and repeatedly used for polishing plural wafers. At this time, the pH value adjustment was conducted with Na₂CO₃. The initial pH value was adjusted to 10.5. The flow rate of the polishing agent was 8 l/min.

In the final polishing, there was employed a single side polishing apparatus as shown in FIG. 3 as a polishing apparatus. Polishing conditions were such that a polishing cloth of an unwoven cloth type (Asker C hardness of 50) was used to polish a silicon wafer surface with stock removal of a small quantity (1 μm or less) under a polishing pressure of 15 kPa. These polishing conditions correspond to those for polishing called the final polishing. As the polishing agent there was used an alkaline solution of an adjusted pH value of 10, and having the silica solid component with a concentration of 0.4 wt %, which was used without circulation.

With the polishing above described, almost no linear defect was observed and, if linear defects were observed on the wafer, there were present only a very small quantity thereof, amounting to 15 counts or less. Besides, if the polishing agent was repeatedly used, almost no increase in the number of the linear defects of the polished wafer was observed and flatness thereof was good.

Then, using the polished wafer as an substrate, epitaxial growth was performed therreon. As a result, no detect was observed on the surface of the epitaxial wafer.

### Comparative Example 4

Polishing was conducted in the same conditions as Example 4 except for using a polishing agent wherein no TMAH was added and the silica particle was in the distorted shape.

As a result, linear defects were observed on each wafer even in the first batch and were increased in number each time when the polishing agent was repeatedly used.

An epitaxial layer was grown on each wafer in a similar way to that in Example 4 and as a result, defects were observed thereon. The defects were observed at almost the same positions as portions where the linear defects were generated.

As described above, by using a polishing agent unique to the method for polishing a wafer of the present invention, generation of linear defects can be prevented.

Incidentally, the method of the present invention is not limited to the embodiment above described. The above embodiment is presented by way of illustration only and any of alterations or modifications thereof is included in the technical scope of the present invention as far as it has substantially the same construction as and effects similar to those of the technical concept set out in the appended claimed.

For example, no specific limitation is placed on an aspect of a polishing apparatus such as a both side polishing apparatus or a single side polishing apparatus. No choice is applied to an aspect of a polishing type such as a batch type in which plural wafers are simultaneously polished or a single wafer type in which a single wafer is polished at a time.

1. A method for polishing a wafer comprising the steps of:
holding a wafer on a rotatable wafer holding plate; and
polishing a surface of the wafer being in contact with a polishing cloth adhered on a rotatable table in such a state that a polishing agent is supplied onto the polishing cloth,
wherein the polishing agent is an alkaline solution which contains silica having particles each in the shape of almost an sphere as a main component and further an organic base or a salt thereof.

2. A method for polishing a wafer comprising the steps of:
holding a wafer on a rotatable wafer holding plate; and
polishing a surface of the wafer being in contact with a polishing cloth adhered on a rotatable table in such a state that a polishing agent is supplied onto the polishing cloth,
wherein the polishing agent is an alkaline solution which contains silica dispersed almost uniformly, the silica having particles each in the shape of almost an sphere and an average particle diameter of 12 nm or less.

3. The method for polishing a wafer according to claim 2, wherein the polishing agent is an alkaline solution which contains the silica as a main component and further an organic base or a salt thereof.

4. The method for polishing a wafer according to claim 1, wherein the organic base or the salt thereof is a quaternary ammonium hydroxide.

5. The method for polishing a wafer according to claim 2, wherein an average particle diameter of the silica in a dispersion state is in the range of from 5 nm to 10 nm.

6. The method for polishing a wafer according to claim 2, wherein a maximum particle diameter of the silica in a dispersion state is 12 nm or less.

7. The method for polishing a wafer according to claim 1, wherein a pH value of the alkaline solution is in the range of from 10 to 13.

8. The method for polishing a wafer according to claim 1, wherein Na₂CO₃ is used for pH adjustment of the alkaline solution.

9. The method for polishing a wafer according to claim 4, wherein the quaternary ammonium hydroxide is tetramethyl ammonium hydroxide.

10. The method for polishing a wafer according to claim 1, wherein the organic base or the salt thereof is added up to a dissolution limit of the polishing agent in use.

11. The method for polishing a wafer according to claim 1, wherein the wafer is a silicon wafer.

12. The method for polishing a wafer according to claim 1, which is performed in a rough polishing step (a primary polishing step and a secondary polishing step) in a mirror polishing process.

13. The method for polishing a wafer according to claim 12, wherein the rough polishing step is the second polishing step.

14. The method for polishing a wafer according to claim 1, wherein the silica is used at a concentration in the range of from 2 to 20 wt %.

15. The method for polishing a wafer according to claim 1, wherein the polishing cloth is of an unwoven cloth type.

16. The method for polishing a wafer according to claim 1, wherein hardness (Asker C hardness) of the polishing cloth is 50 or more.

17. The method for polishing a wafer according to claim 1, wherein stock removal of the wafer is 1 μm or more.
